(19) United States
(12) Patent Application Publication
(10) Pub. No.: US 2024/0276842 A1
(43) Pub. Date: Aug. 15, 2024

(54) DISPLAY APPARATUS AND METHOD OF MANUFACTURING THE SAME

(71) Applicant: Samsung Display Co., Ltd., Yongin-si (KR)

(72) Inventors: Youngdo Kim, Yongin-si (KR); Junyoung Lee, Yongin-si (KR); Junehyoung Park, Yongin-si (KR); Jeongweon Seo, Yongin-si (KR); Junwoo You, Yongin-si (KR); Changmoo Lee, Yongin-si (KR); Sukwon Jung, Yongin-si (KR)

(21) Appl. No.: 18/429,703

(22) Filed: Feb. 1, 2024

(30) Foreign Application Priority Data
Feb. 2, 2023 (KR) 10-2023-0014403

(51) Int. Cl. H10K 59/80; H10K 59/12

(52) U.S. Cl. CPC H10K 59/873; H10K 59/1201; H10K 59/8792

(57) ABSTRACT

A display apparatus includes a substrate, a display layer disposed on a first surface of the substrate, and a protective member disposed on a second surface of the substrate located opposite to the first surface, wherein the protective member includes a resin coated layer, wherein the resin coated layer includes a plurality of first fillers having heat-dissipating properties, a binder, and a foaming agent.

This application claims priority to Korean Patent Application No. 10-2023-0014403, filed on Feb. 2, 2023, and all the benefits accruing therefrom under 35 U.S.C. § 119, the content of which in its entirety is herein incorporated by reference.

### BACKGROUND

### 1.Field

One or more embodiments relate to a structure of a display apparatus and a method of manufacturing the display apparatus.

### 2. Description of the Related Art

A display apparatus visually displays data. The display apparatus may include a substrate divided into a display area and a peripheral area. A scan line is insulated from a data line in the display area, and a plurality of pixels may be arranged in the display area. In addition, a thin-film transistor and a sub-pixel electrode electrically connected to the thin-film transistor may be provided in the display area, wherein each of the thin-film transistor and the sub-pixel electrode corresponds to each of the pixels. In addition, an opposite electrode may be provided in the display area, wherein the opposite electrode is commonly provided to the pixels. Various wirings, a scan driver, a data driver, a controller, a pad portion, and the like, which are configured to transfer electrical signals to the display area, may be provided in the peripheral area.

The usage of display apparatuses has diversified. Accordingly, various attempts have been made to design a display apparatus with improved quality.

### SUMMARY

One or more embodiments include a display apparatus with a heat-dissipation function, an electromagnetic wave-shielding function, a light-blocking function, and a shock absorption function. However, these technical problems are just examples, and the disclosure is not limited thereto.

Additional aspects will be set forth in part in the description which follows and, in part, will be apparent from the description, and/or may be learned by practice of the embodiments of the disclosure.

According to one or more embodiments, a display apparatus includes a substrate, a display layer disposed on a first surface of the substrate, and a protective member disposed on a second surface of the substrate to be located opposite to the first surface, wherein the protective member includes a resin coated layer, and wherein the resin coated layer includes a plurality of first fillers having a heat-dissipating characteristic, a binder, and a foaming agent.

The plurality of first fillers may include plate-shaped fillers or linear fillers.

Some of the plurality of first fillers may be in contact with each other to form a heat-dissipating path.

The plurality of first fillers may include at least one of a carbon-based material and a ceramic-based material.

The carbon-based material may include at least one of graphite, carbon nanotube (CNT), and carbon fiber, and the ceramic-based material may include at least one of boron nitride (BN), aluminum nitride (AlN), beryllium oxide (BeO), silicon carbide (SiC), and aluminum oxide (Al₂O₃).

The plurality of first fillers may be included in content of about 50 wt % to about 80 wt % with respect to a total weight of the resin coated layer.

A particle diameter of at least one of the plurality of first fillers may be about 10 μm to about 100 μm.

The resin coated layer may further include a plurality of second fillers configured to absorb electromagnetic waves, wherein the plurality of second fillers may include at least one of a carbon-based material and a metal-based material.

The carbon-based material may include at least one of carbon fiber and carbon nanotube (CNT), and the metal-based material may include at least one of silver-copper (Ag-Cu), nickel-copper (Ni-Cu), Ag nano wire, and silver-nickel (Ag-Ni) powder.

The plurality of second fillers may be included in content of about 1 wt % to about 10 wt % with respect to a total weight of the resin coated layer.

The plurality of first fillers and the plurality of second fillers may be included in content of about 51 wt % to about 90 wt % with respect to a total weight of the resin coated layer.

The binder may include at least one of an acrylic resin, a urethane resin, a silicone resin, and a rubber resin.

The foaming agent may be a thermo-expandable microcapsule.

A particle diameter of the foaming agent may be about 10 μm to about 100 μm.

The resin coated layer may further include a first light-blocking material, wherein the first light-blocking material may include at least one of carbon black, black pigment, and black dye.

The first light-blocking material may be included in content of about 1 wt % to about 5 wt % with respect to a total weight of the resin coated layer.

A thickness of the resin coated layer after curing may be about 100 μm to about 300 μm.

An optical density of the resin coated layer may be about 3.0 or more.

A thermal conductivity of the resin coated layer in a planar direction may be about 10 W/mK to about 50 W/mK.

The resin coated layer may have an impact resistance of about 10 MPa to about 40 MPa or less when an about 2.0 g-steel ball is dropped from a height of about 10 cm.

An electromagnetic wave-shielding rate of the resin coated layer may be about 40 dB to about 90 dB.

The protective member may further include a metal base layer, wherein the metal base layer may be disposed on an opposite side of the substrate with the resin coated layer therebetween.

The metal base layer may include copper (Cu).

A thickness of the metal base layer may be about 5 μm to about 50 μm.

The protective member may further include an adhesive layer disposed between the substrate and the resin coated layer, wherein the adhesive layer may include a pressure sensitive adhesive (PSA).

According to one or more embodiments, a method of manufacturing a display apparatus includes forming a display layer disposed on one surface of a substrate, and forming a protective member disposed on another surface to be located opposite to the one surface of the substrate, wherein the forming of the protective member includes forming a resin coated layer including a plurality of first fillers having a heat-dissipating characteristic, a binder, and a foaming agent.

The forming of the resin coated layer may include preparing a mixture of the plurality of first fillers, the binder, the foaming agent, and a solvent, wherein a boiling point of the solvent may be about 100° C. to about 200° C.

The forming of the resin coated layer may further include coating the other surface of the substrate with the mixture, and curing the coated mixture to remove the solvent, and expanding the foaming agent.

The coating of the mixture may use one of a printing method, a coating method, and a dispensing method.

The curing of the mixture may include heat-treating the mixture at a temperature of about 25° C. to about 100° C. or less.

A particle diameter of the foaming agent expanded after the heat-treating may be about 10 μm to about 100 μm.

The forming of the protective member may include forming a metal base layer including copper (Cu), coating the metal base layer with the resin coated layer, and curing the mixture coating to remove the solvent, and expanding the foaming agent.

The forming of the protective member may further include forming an embossed shape on another surface located opposite to one surface of the resin coated layer facing the metal base layer.

The forming of the protective member may further include forming an adhesive layer on another surface opposite to one surface of the resin coated layer facing the metal base layer.

The method may further include laminating the protective member on the other surface of the substrate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of a display apparatus according to an embodiment;

FIG. 2 is a cross-sectional view of a display apparatus according to an embodiment;

FIG. 3 is a schematic plan view of a display panel of a display apparatus according to an embodiment;

FIG. 4 is an equivalent circuit diagram of one of the pixels in a display panel according to an embodiment;

FIG. 5 is a cross-sectional view of a portion of a display panel according to an embodiment;

FIG. 6 is a cross-sectional view of a portion of a display panel according to an embodiment;

FIG. 7A is a schematic view of a portion of a resin coated layer according to an embodiment;

FIG. 7B is a schematic view of a portion of a resin coated layer according to an embodiment;

FIG. 8 is a cross-sectional view of a portion of a display panel according to another embodiment;

FIG. 9 is a schematic view of an apparatus for manufacturing a display panel, according to another embodiment;

FIG. 10 is a cross-sectional view of a portion of a display panel according to another embodiment; and

FIG. 11 is a schematic view of an apparatus for manufacturing a display panel, according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

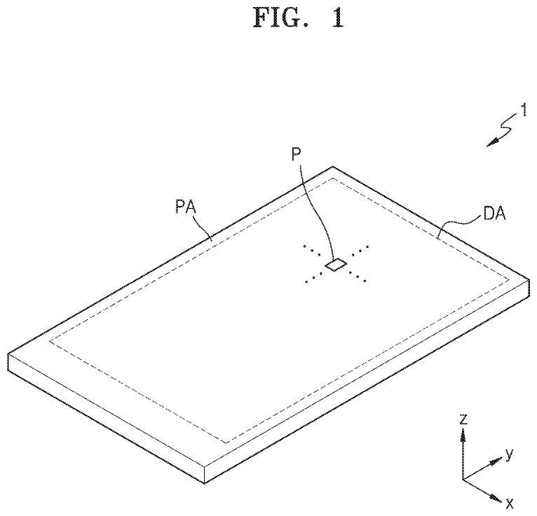

FIG. 1 is a schematic perspective view of a display apparatus 1 according to an embodiment.

In an embodiment and referring to FIG. 1, the display apparatus 1 may include a display area DA and a peripheral area PA outside the display area DA. The display area DA may be configured to display images through pixels P arranged and located in the display area DA. The peripheral area PA is arranged outside the display area DA and is a non-display area in which images are not displayed. The peripheral area PA may surround the display area DA partially or entirely. A driver and the like configured to provide electric signals and/or power to the display area DA may be arranged in the peripheral area PA. A pad may be arranged in the peripheral area PA, wherein the pad may be a region to which electronic elements and/or a printed circuit board may be electrically connected.

In an embodiment, although FIG. 1 shows that the display area DA is a polygon (e.g., a quadrangle) in which a length thereof in an x direction is less than a length thereof in a y direction, the display area DA may be a polygon (e.g., a quadrangle) in which a length thereof in the y direction is less than a length thereof in the x direction in another embodiment. Although FIG. 1 shows the display area DA is approximately a quadrangle, the embodiment is not limited thereto. As another embodiment, the display area DA may have various shapes such as an N-gon (where N is a natural number of 3 or more), a circle, or an ellipse. Although it is shown in FIG. 1 that the display area DA has a shape in which a corner of the display area DA includes a vertex at which a straight line meets a straight line, the display area DA may be a polygon having rounded corners.

Hereinafter, for convenience of description, although the case where the display apparatus 1 is a smartphone is described, the display apparatus 1 according to an embodiment is not limited thereto. The display apparatus 1 may be applicable to various products including televisions, notebook computers, monitors, advertisement boards, Internet of things (IoTs) as well as portable electronic apparatuses including mobile phones, smart phones, tablet personal computers (PCs), mobile communication terminals, electronic organizers, electronic books, portable multimedia players (PMPs), navigations, and/or ultra mobile personal computers (UMPCs). In addition, the display apparatus 1 according to an embodiment may be applicable to wearable devices including smartwatches, watchphones, glasses-type displays, and/or head-mounted displays (HMDs). In addition, in an embodiment, the display apparatus 1 may be applicable to a display screen in instrument panels for automobiles, center fascias for automobiles, and/or center information displays (CIDs) arranged on a dashboard, room mirror displays that replace side mirrors of automobiles, and/or displays of an entertainment system arranged on the backside of front seats for backseat passengers in automobiles.

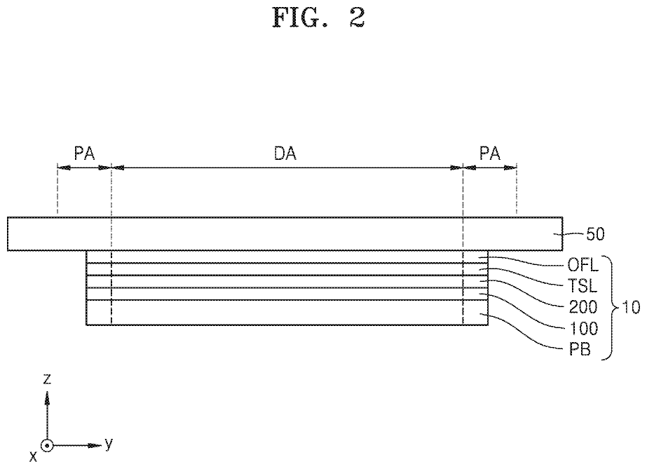

FIG. 2 is a schematic cross-sectional view of the display apparatus 1 according to an embodiment.

As shown in FIG. 2, the display apparatus 1 according to an embodiment may include a display panel 10 and a cover window 50.

In an embodiment, the display panel 10 may be a light-emitting display panel including a light-emitting element as a display element. As an example, the display panel 10 may be an organic light-emitting display panel that uses an organic light-emitting diode that includes an organic emission layer, an ultra-miniature light-emitting diode display panel that uses a micro light-emitting diode, a quantum-dot light-emitting display panel that uses a quantum-dot light-emitting diode including a quantum-dot emission layer, and/or an inorganic light-emitting display panel that uses an inorganic light-emitting element including an inorganic semiconductor.

In an embodiment, the display panel 10 may be a rigid display panel that has a rigidity and thus is not easily bent, and/or a flexible display panel that has a flexibility and thus is easily bendable, foldable, and/or rollable. As an example, the display panel 10 may include a foldable display panel that is foldable and unfoldable, a curved display panel that has a curved display surface, a bendable display panel in which a region except a display surface is bendable, a rollable display panel that is rollable and unrollable, and a stretchable display panel that is stretchable.

In an embodiment, the display panel 10 may include a substrate 100, a display layer 200, a touchscreen layer TSL, an optical functional layer OFL, and a protective member PB.

In an embodiment, the substrate 100 may include an insulating material such as glass, quartz, a polymer resin and/or the like. The substrate 100 may be a rigid substrate and/or a flexible substrate that is bendable, foldable, and/or rollable. As an example, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multi-layered structure including a layer that includes the polymer resin and/or an inorganic layer. As an example, the substrate 100 may include two layers including the polymer resin, and an inorganic barrier layer therebetween.

In an embodiment, the display layer 200 may be disposed on the substrate 100. The display layer 200 may be a layer including the pixels and configured to display images. The display layer 200 may include a circuit layer, a display element layer, and/or an encapsulation member, wherein the circuit layer may include thin-film transistors, display elements that may be disposed in the display element layer, and the encapsulation member that may encapsulate the display element layer.

In an embodiment, the display layer 200 may be divided into the display area DA and the peripheral area PA. The display area DA may be a region in which pixels are arranged to display images. The peripheral area PA may be arranged outside the display area DA and may be a region in which images are not displayed. The peripheral area PA may be arranged to surround the display area DA. The peripheral area PA may be a region from an outside of the display area DA to an edge of the display panel 10. Not only the pixels but also pixel circuits, scan lines, data lines, power lines, and the like may be arranged in the display area DA, wherein the pixel circuits may be configured to drive the pixels, the scan lines, the data lines, and/or the power lines which are connected to the pixel circuit. A scan driver, fan-out wirings and/or the like may be arranged in the peripheral area PA, wherein the scan driver may be configured to apply scan signals to the scan lines, and/or the fan-out wirings which connect the data lines to the display driver.

Various functional layers may be disposed on the display layer 200 depending on a design. In an embodiment, the touchscreen layer TSL may be disposed on the display layer 200. The touchscreen layer TSL may include touch electrodes and be a layer configured to sense whether users touch.

In an embodiment, the touchscreen layer TSL may be directly formed on the encapsulation member of the display layer 200. Alternatively, the touchscreen layer TSL may be formed separately, and then coupled to the encapsulation member of the display layer 200 through an adhesive layer such as an optically clear adhesive (OCA).

In an embodiment, the optical functional layer OFL may be disposed on the touchscreen layer TSL. The optical functional layer OFL may include an anti-reflection layer. The anti-reflection layer may reduce reflectivity of light (external light) incident toward the display apparatus 1 from the outside.

In an embodiment, the anti-reflection layer may include a polarizing film. The polarizing film may include a linear polarizing plate and/or a phase-retarding film such as a λ/4 (quarter-wave) plate. The phase-retarding film may be disposed on the touchscreen layer TSL, and the linear polarizing film may be disposed on the phase-retarding film.

In an embodiment, the cover window 50 may be disposed on the optical functional layer OFL. The cover window 50 may be attached to the optical functional layer OFL by a transparent adhesive member such as an optical transparent adhesive (OCA).

In an embodiment, the cover window 50 may be disposed on the display panel 10 to cover the upper surface of the display panel 10. Accordingly, the cover window 50 may be configured to protect the upper surface of the display panel 10.

In an embodiment, the cover window 50 may be a flexible window. The cover window 50 may be configured to protect the display panel 10 while easily bending according to external force without occurrence of cracks and the like. The cover window 50 may include glass, sapphire, and/or plastic. The cover window 50 may be, for example, ultra-thin glass (UTG) and/or colorless polyimide (CPI). In an embodiment, the cover window 50 may have a structure in which a flexible polymer layer is disposed on one surface of a glass substrate, and/or include only a polymer layer.

In an embodiment, the protective member PB may be disposed under the substrate 100. The protective member PB may be configured to protect the display panel 10. Specifically, the protective member PB may be configured to protect impacts transferred from below the display panel 10 and prevent the shape of elements disposed on the protective member PB from being transformed. In addition, the protective member PB may include a material having excellent thermal conductivity to perform a heat dissipation function. The protective member PB may include a material having confuctivity to absorb electromagnetic waves and/or prevent electrical interferences. Together, the protective member PB may include a light-blocking material to block light from the outside of the display apparatus 1 and/or reduce reflectivity of light transmitted from the upper portion. Accordingly, the protective member PB may be configured to improve the reliability of the display panel 10.

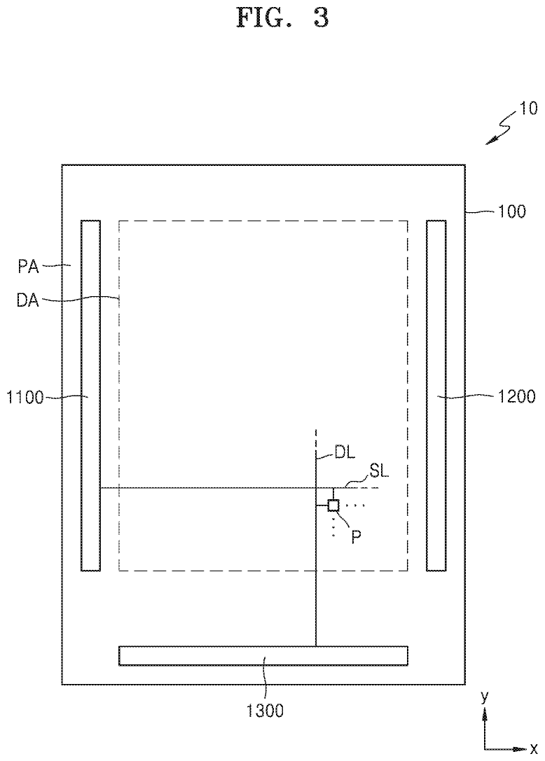

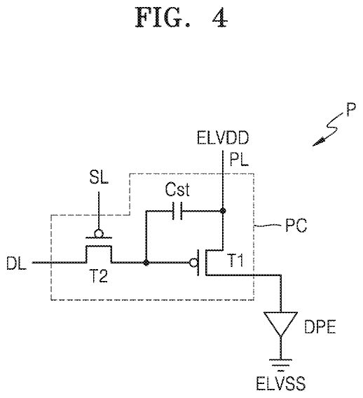

FIG. 3 is a schematic plan view of a portion of the display panel 10 of the display apparatus 1 according to an emboiment, and FIG. 4 is an equivalent circuit diagram of one of pixels in the display panel 10 according to an embodiment.

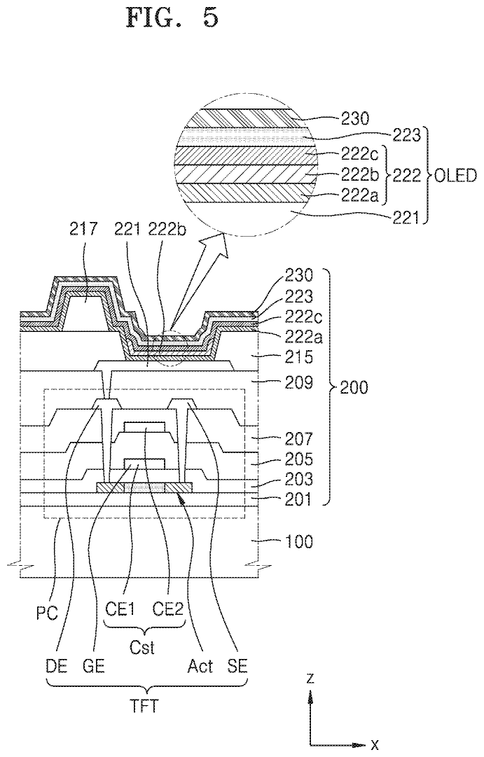

In an embodiment, the display panel 10 may include the display area DA. The display panel 10 may include the plurality of pixels P arranged in the display area DA. As shown in FIG. 5, each pixel P may include a pixel circuit PC and a display element DPE, wherein the display element DPE is connected to the pixel circuit PC and is, for example, an organic light-emitting diode OLED. The pixel circuit PC may include a first transistor T1, a second transistor T2. and a storage capacitor Cst. Each pixel P may emit, for example, red, green, or blue light, or emit red, green, blue, or white light by using the organic light-emitting diode OLED. The first transistor T1 and the second transistor T2 may each be implemented as thin-film transistors.

In an embodiment, the second transistor T2 may be a switching transistor, may be connected to a scan line SL and/or a data line DL, and/or configured to transfer a data voltage to the first transistor T1 according to a switching voltage, the data voltage being input from the data line DL, and/or the switching voltage being input from the scan line SL. The storage capacitor Cst may be connected to the second transistor T2 and a driving voltage line PL and may be configured to store a voltage corresponding to a difference between a voltage transferred from the second transistor T2 and a first power voltage ELVDD that is supplied to the driving voltage line PL.

In an embodiment, the first transistor T1 may be a driving transistor, may be connected to the driving voltage line PL and the storage capacitor Cst, and may be configured to control a driving current according to the voltage stored in the storage capacitor Cst, wherein the driving current is flowing from the driving voltage line PL to the organic light-emitting diode OLED. The organic light-emitting diode OLED may be configured to emit light having a preset brightness corresponding to the driving current. An opposite electrode (e.g., a cathode) of the organic light-emitting diode OLED may receive a second power voltage ELVSS.

Although in an embodiment it is described with reference to FIG. 4 that the pixel circuit PC includes two transistors and one storage capacitor, the embodiment is not limited thereto. That is, the number of thin-film transistors and/or the number of capacitors included in the pixel circuit PC may be variously changed depending on the design of the pixel circuit PC. As an example, the pixel circuit PC may further include four or more thin-film transistors as well as the two thin-film transistors. In addition, the pixel circuit PC may further include one or more capacitors as well as the storage capacitor Cst.

In an embodiment and referring to FIG. 3, a first scan driver 1100, a second scan driver 1200, a data driver 1300, a main power line (not shown) and/or the like may be arranged in the peripheral area PA, wherein the first scan driver 1100 and/or the second scan driver 1200 may be configured to provide scan signals to each pixel P, the data driver 1300 may be configured to provide data signals to each pixel P, and/or the main power line may be configured to provide first and second power voltages. The first scan driver 1100 and the second scan driver 1200 may each be arranged in the peripheral area PA, and/or be respectively arranged on two opposite sides of the display area DA with the display area DA therebetween.

Although, in an embodiment, it is shown in FIG. 3 that the data driver 1200 is disposed adjacent to one side of the substrate 100, the data driver 1200 may be disposed on a flexible printed circuit board (FPCB) to be electrically connected to a pad arranged on one side of the display panel 10 in another embodiment.

FIG. 5 is a schematic cross-sectional view of a portion of the display panel 10 according to an embodiment.

In an embodiment and referring to FIG. 5, the pixel circuit PC may be disposed on the substrate 100, and/or the organic light-emitting diode OLED may be disposed on the pixel circuit PC, wherein the organic light-emitting diode OLED is the display element DPE (see FIG. 4) electrically connected to the pixel circuit PC. The substrate 100 may include glass and/or polymer resin. The substrate 100 may include a single layer or a multi-layer.

In an embodiment, a buffer layer 201 may be disposed on the substrate 100. The buffer layer 201 may be configured to reduce and/or block foreign materials, moisture, and/or external air penetrating from below the substrate 100 and/or may increase flatness of the upper surface of the substrate 100. The buffer layer 201 may include an inorganic material, an organic material, and/or an organic/inorganic composite material, and may include a single layer and/or a multi-layer including an inorganic material and/or an organic material, the inorganic material including oxide and/or nitride. A barrier layer (not shown) may be further arranged between the substrate 100 and the buffer layer 201, wherein the barrier layer may block penetration of external air.

In an embodiment, the pixel circuit PC may be disposed on the buffer layer 201. The pixel circuit PC may include a thin-film transistor TFT and/or a storage capacitor Cst. The thin-film transistor TFT may include a semiconductor layer Act, a gate electrode GE, a source electrode SE, and a drain electrode DE. In the embodiment, although a top-gate type thin-film transistor in which the gate electrode GE is disposed over the semiconductor layer Act with a gate insulating layer 203 therebetween is shown, the thin-film transistor TFT may be a bottom-gate type thin-film transistor in another embodiment.

In an embodiment, the semiconductor layer Act may be disposed on the buffer layer 201. The semiconductor layer Act may include a channel region, a drain region, and/or a source region, the drain region and/or the source region being doped with impurities and/or being respectively on two opposite sides of the channel region. In this case, the impurities may include N-type impurities and/or P-type impurities. The semiconductor layer Act may include amorphous silicon and/or polycrystalline silicon. As a specific example, the semiconductor layer Act may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and/or zinc (Zn). In addition, the semiconductor layer Act may include a Zn-oxide-based material and/or may include Zn-oxide, In-Zn oxide, and/or Ga-In-Zn oxide.

In addition, the semiconductor layer Act may include In-Ga-Zn-O (IGZO), In-Sn-Zn-O (ITZO), and/or In-Ga-Sn-Zn-O (IGTZO) semiconductor containing metal such as indium (In), gallium (Ga), and/or stannum (Sn) in ZnO.

In an embodiment, the gate electrode GE may be disposed over the semiconductor layer Act to overlap at least a portion of the semiconductor layer Act. Specifically, the gate electrode GE may overlap the channel region of the semiconductor layer Act. The gate electrode GE may include various conductive materials including molybdenum (Mo), aluminum (Al), copper (Cu), titanium (Ti), and the like and may have various layered structures. As an example, the gate electrode GE may include a Mo layer and/or an Al layer and/or have a multi-layered structure of a Mo/Al/Mo. In addition, in an embodiment, the gate electrode GE may have a multi-layered structure including an indium tin oxide (ITO) layer covering a metal material.

In an embodiment, the gate insulating layer 203 between the semiconductor layer Act and the gate electrode GE may each include an inorganic insulating material including silicon oxide, silicon nitride, silicon oxynitride, aluminum oxide, titanium oxide, tantalum oxide, hafnium oxide and/or the like. The gate insulating layer 203 may include a single layer and/or a multi-layer including the above materials.

In an embodiment, the source electrode SE and/or the drain electrode DE may each include various conductive materials including molybdenum (Mo), aluminum (Al), copper (Cu), titanium (Ti), and/or the like and have various layered structures. As an example, the source electrode SE and/or the drain electrode DE may each include a Ti layer and/or an Al layer and/or have a multi-layered structure of a Ti/Al/Ti. The source electrode SE and/or the drain electrode DE may be connected to a source region and a drain region of the semiconductor layer Act through contact holes, respectively. In addition, in an embodiment, the source electrode SE and/or the drain electrode DE may each have a multi-layered structure including an indium tin oxide (ITO) layer covering a metal material.

In an embodiment, the storage capacitor Cst may include a lower electrode CE1 and/or an upper electrode CE2 overlapping each other with a first interlayer insulating layer 205 therebetween. The storage capacitor Cst may overlap the thin-film transistor TFT. The lower electrode CE1 and the upper electrode CE2 may overlap each other with the first interlayer insulating layer 205 therebetween and may constitute a capacitance. In this case, the first interlayer insulating layer 205 serves as a dielectric layer of the storage capacitor Cst. With regard to this, it is shown in FIG. 5 that the gate electrode GE of the thin-film transistor TFT serves as the lower electrode CE1 of the storage capacitor Cst. In another embodiment, the storage capacitor Cst may not overlap the thin-film transistor TFT. The storage capacitor Cst may be covered by a second interlayer insulating layer 207.

In an embodiment, the first interlayer insulating layer 205 and/or the second interlayer insulating layer 207 may each include an inorganic insulating material including silicon oxide, silicon nitride, silicon oxynitride, aluminum oxide, titanium oxide, tantalum oxide, hafnium oxide and/or the like. The first interlayer insulating layer 205 and/or the second interlayer insulating layer 207 may each include a single layer and/or a multi-layer including the above materials.

In an embodiment, although the insulating layers 203, 205, and 207 and the interlayer insulating layer 205 including the inorganic material may be formed by chemical vapor deposition (CVD) or atomic layer deposition (ALD), the embodiment is not limited thereto.

In an embodiment, the pixel circuit PC including the thin-film transistor TFT and the storage capacitor Cst may be covered by an organic insulating layer 209. As an example, the organic insulating layer 209 may cover the source electrode SE and the drain electrode DE. The organic insulating layer 209 may be disposed over the substrate 100 in the display area and/or the peripheral area outside the display area. The organic insulating layer 209 may be a planarization insulating layer and/or may include an approximately flat upper surface. The organic insulating layer 209 may include an organic insulating material including a general-purpose polymer such as polymethylmethacrylate (PMMA) and/or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof. In an embodiment, the organic insulating layer 209 may include polyimide.

In an embodiment, a pixel electrode 221 may be disposed on the organic insulating layer 209. The pixel electrode 221 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), and/or a compound thereof. In another embodiment, the pixel electrode 221 may further include a layer on/under the reflective layer, wherein the layer may include ITO, IZO, ZnO, In₂O₃ and/or the like.

In an embodiment, a bank layer 215 may be disposed on the pixel electrode 221. The bank layer 215 may include an opening that exposes the upper surface of the pixel electrode 221, and/or cover the edges of the pixel electrode 221. The bank layer 215 may include an organic insulating material. Alternatively, the bank layer 215 may include an inorganic insulating material such as silicon nitride, silicon oxynitride, and/or silicon oxide. Alternatively, the bank layer 215 may include an organic insulating material and/or an inorganic insulating material.

In an embodiment, an intermediate layer 222 may include an emission layer 222b. The emission layer 222b may include, for example, an organic material. The emission layer 222b may include a polymer organic material and/or a low-molecular weight organic material configured to emit light having a preset color. The intermediate layer 222 may include a first functional layer 222a and/or a second functional layer 222c, wherein the first functional layer 222a may be located under the emission layer 222b, and the second functional layer 222c may be located on the emission layer 222b.

In an embodiment, the first functional layer 222a may include a single layer and/or a multi-layer. As an example, in the case where the first functional layer 222a includes a polymer material, the first functional layer 222a may include a hole transport layer (HTL), which has a single-layered structure, and/or may include polyethylene dihydroxythiophene (PEDOT: poly-(3,4)-ethylene-dihydroxy thiophene) and/or polyaniline (PANI: polyaniline). In the case where the first functional layer 222a includes a low-molecular weight material, the first functional layer 222a may include a hole injection layer (HIL) and/or an HTL.

In an embodiment, the second functional layer 222c may be optional. As an example, the first functional layer 222a and/or the emission layer 222b may include a polymer material, the second functional layer 222c may be formed. The second functional layer 222c may include a single layer and/or a multi-layer. The second functional layer 222c may include an electron transport layer (ETL) and/or an electron injection layer (EIL).

In an embodiment, the emission layer 222b of the intermediate layer 222 may be arranged for each pixel in the display area DA. The emission layer 222b may be arranged to overlap the opening of the bank layer 215 and/or the pixel electrode 221. Each of the first and second functional layers 222a and 222c of the intermediate layer 222 may be formed as a single layer.

In an embodiment, an opposite electrode 223 may include a conductive material having a low work function. As an example, the opposite electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), and/or an alloy thereof. Alternatively, the opposite electrode 223 may further include a layer on the (semi) transparent layer, the layer including ITO, IZO, ZnO, and/or In₂O₃. The opposite electrode 223 may be a single layer and/or may be formed to cover the plurality of pixel electrodes 221 in the display area DA. The intermediate layer 222 and/or the opposite electrode 223 may be formed by thermal deposition.

In an embodiment, a spacer 217 may be disposed on the bank layer 215. The spacer 217 may be configured to prevent the light-emitting diode and/or the like from being damaged by securing a preset space over the display element.

In an embodiment, the spacer 217 may include an organic insulating material such as polyimide. Alternatively, the spacer 217 may include an inorganic insulating material such as silicon nitride and/or silicon oxide, and/or include an organic insulating material and an inorganic insulating material. In addition, the spacer 217 may include a material different from a material of the bank layer 215. Alternatively, the spacer 217 may include the same material as that of the bank layer 215. In this case, the bank layer 215 and/or the spacer 217 may be simultaneously formed during a mask process that uses a half-tone mask and/or the like.

In an embodiment, a capping layer 230 may be disposed on the opposite electrode 223. The capping layer 230 may include lithium fluoride (LiF), an inorganic material, and/or an organic material. In an embodiment, the capping layer 230 may be omitted.

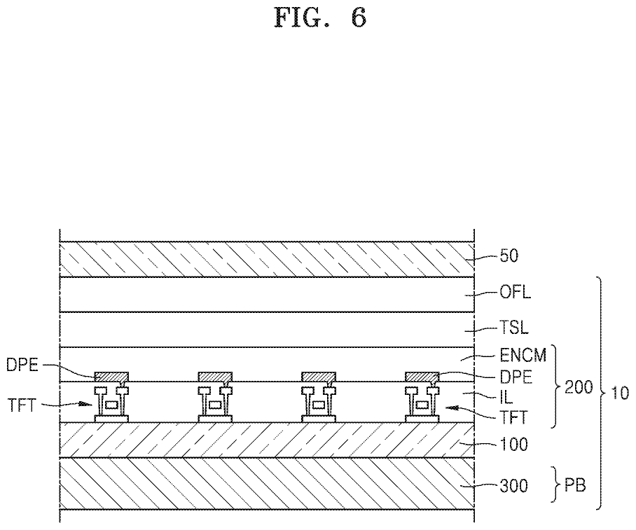

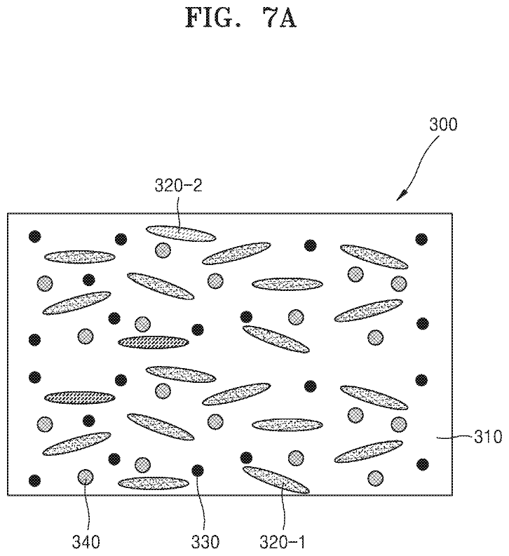

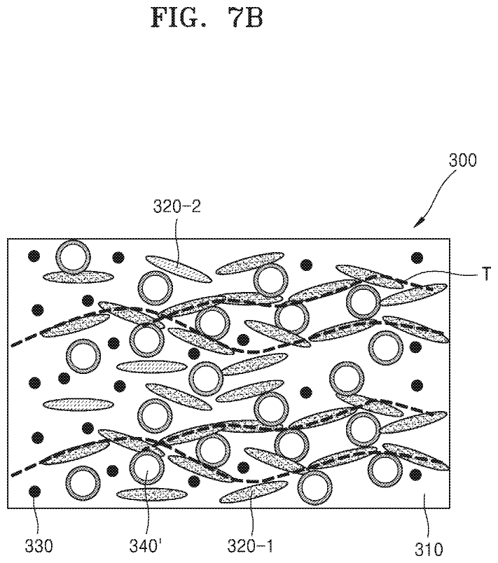

FIG. 6 is a schematic cross-sectional view of a portion of the display panel 10 according to an embodiment, and FIGS. 7A and 7B are schematic views of a portion of the resin coated layer according to an embodiment. Hereinafter, because the same reference numerals denote the same elements, repeated descriptions of the same elements are omitted.

In an embodiment, as shown in FIG. 6, the cover window 50 may be disposed on the display panel 10. The cover window 50 may be disposed on the display panel 10 to cover the display panel 10 entirely.

In an embodiment, the display panel 10 mayinclude the substrate 100, the display layer 200 disposed on the upper surface of the substrate 100, the functional layers (e.g., the touchscreen layer TSL and the optical functional layer OFL) disposed on the upper surface of the display layer 200, and the protective member PB disposed under the substrate 100.

In an embodiment, an insulating layer may be disposed between the substrate 100 and the display layer 200 and/or inside the display layer 200.

In an embodiment, the display layer 200 of the display panel 10 may further include an encapsulation member ENCM. The encapsulation member ENCM may be an encapsulation layer configured to protect the display elements of the display layer 200 from external moisture and/or oxygen and/or the like. The encapsulation layer may include at least one organic encapsulation layer and/or at least one inorganic encapsulation layer. As an example, the encapsulation layer may include a first inorganic encapsulation layer, an organic encapsulation layer, and/or a second inorganic encapsulation layer.

In an embodiment, as described above with reference to FIG. 5, in the case where the display element is the organic light-emitting diode OLED (see FIG. 5), the first inorganic encapsulation layer may cover the opposite electrode 223 (see FIG. 5) and include silicon oxide, silicon nitride, and/or silicon trioxynitride. The capping layer 230 (see FIG. 5) may be disposed between the first inorganic encapsulation layer and the opposite electrode. Because the first inorganic encapsulation layer may be formed along the structure thereunder, the organic encapsulation layer may be formed to cover the first inorganic encapsulation layer such that the upper surface of the organic encapsulation layer is flat. The organic encapsulation layer may include at least one material among polyethylene terephthalate, polyethylene naphthalate, polycarbonate, polyimide, polyethylene sulfonate, polyoxymethylene, polyarylate, and/or hexamethyldisiloxane. The second inorganic encapsulation layer may be arranged to cover the organic encapsulation layer and may include silicon oxide, silicon nitride, and/or silicon trioxynitride.

In an embodiment, the protective member PB may be disposed under the substrate 100. The protective member PB may include a resin coated layer 300. The resin coated layer 300 may include a binder 310, a first filler 320-1, a second filler 320-2, a light-blocking material 330, and a foaming agent 340. A thickness of the resin coated layer 300 after curing may be about 100 μm to about 300 μm.

In an embodiment, the first filler 320-1 may have a heat dissipation characteristic. Accordingly, the first filler 320-1 mayinclude a material having excellent thermal conductivity. The first filler 320-1 mayinclude at least one of a carbon-based material and a ceramic-based material. Specifically, in the case where the first filler 320-1 includes a carbon-based material, the first filler 320-1 may include at least one of graphite, carbon nanotube, and carbon fiber. In the case where the first filler 320-1 includes a ceramic-based material, the first filler 320-1 may include at least one of boron nitride (BN), aluminum nitride (AlN), beryllium oxide (BeO), silicon carbide (SiC), and aluminum oxide (Al₂O₃).

In an embodiment, the first filler 320-1 may be a plate-shaped filler or a linear filler. In this case, the particle diameter of the first filler 320-1 may be about 10 μm to about 100 μm. Accordingly, some of the first fillers 320-1 may contact each other to form a heat dissipation path. Specifically, in the case where the first filler 320-1 includes a plate-shaped filler, some of the first fillers 320-1 may plane-contact each other to form a heat dissipation path. In the case where the first filler 320-1 includes a linear filler, some of the first fillers 320-1 may linearly contact each other to form a heat dissipation path. As an example, in the case where the first filler 320-1 includes a spherical filler, because the first fillers 320-1 may inevitably point-contact each other, it may be difficult to form a heat dissipation path. However, as in FIG. 7A, in the case where the first filler 320-1 has a plate shape, because the contact area between the fillers is widened, a heat dissipation path may be easily formed.

In an embodiment, the first fillers 320-1 may be included in the amount of about 50 wt % to about 80 wt % with respect to a total weight of the resin coated layer 300. In this case, the first fillers 320-1 may include a carbon-based material and a ceramic-based material mixed with each other and occupy about 50 wt % to about 80 wt % of the resin coated layer 300. However, the embodiment is not limited thereto and the first fillers 320-1 may include only a carbon-based material or include only a ceramic-based material.

In an embodiment, because the first fillers 320-1 occupies about 50 wt % to about 80 wt % which is more than half the total weight of the resin coated layer 300, the first fillers 320-1 arranged adjacent to each other may contact each other to easily form a heat dissipation path. Accordingly, the protective member PB including the first fillers 320-1 may be configured to effectively dissipate heat occurring from the display panel 10.

In an embodiment, the second filler 320-2 may have a characteristic of shielding electromagnetic waves. Accordingly, the second filler 320-2 may include a material having excellent electrical conductivity. The second filler 320-2 may include at least one of a carbon-based material and a metal-based material. Specifically, in the case where the second filler 320-2 includes a carbon-based material, the second filler 320-2 may include at least one of carbon fiber and carbon nanotube (CNT). In the case where the second filler 320-2 includes a metal-based material, the second filler 320-2 may include at least one of silver-copper (Ag-Cu), nickel-copper (Ni-Cu), silver nano wire, and silver-nickel (Ag-Ni) powder.

In an embodiment, in the case where the first fillers 320-1 includes a carbon-based material, the first fillers 320-1 may be configured to block some of the electromagnetic waves. However, the second filler 320-2 may be further added to further increase an electromagnetic wave shielding rate. The second fillers 320-2 may be included in the content of about 1 wt % to about 10 wt % with respect to the total weight of the resin coated layer 300. In an embodiment, an electromagnetic wave shielding rate of the resin coated layer 300 including the first fillers 320-1 and the second fillers 320-2 may be about 40 dB to about 90 dB, and preferably about 60 dB to about 80 dB.

Consequently, in an embodiment, the content of the first fillers 320-1 and the second fillers 320-2 included in the resin coated layer 300 may be about 51 wt % to about 90 wt % with respect to the total weight of the resin coated layer 300. More preferably, the first fillers 320-1 and the second fillers 320-2 may occupy about 85 wt % or less with respect to the total weight of the resin coated layer 300. This is because binders configured to fix the first fillers 320-1 and the second fillers 320-2 may be sufficiently included. In addition, in the case where the first fillers 320-1 and/or the second fillers 320-2 are excessively included, adhesiveness of the resin coated layer 300 may be reduced. That is, in the case where the first fillers 320-1 and the second fillers 320-2 occupy about 85 wt % or less with respect to the total weight of the resin coated layer 300, the resin coated layer 300 may be coated and adhered to the substrate 100 without a separate adhesive layer.

Next, in an embodiment, the binder 310 may be configured to fix the first fillers 320-1 and/or the second fillers 320-2. The binder 310 may include at least one of an acrylic resin, a urethane resin, a silicone resin, and/or a rubber resin. Specifically, the binder 310 may include acrylate, urethane, urethane acrylate, silicone, rubber, and/or a combination thereof. However, the embodiment is not limited thereto and as long as it is a material having sufficient bonding force that may fix the first fillers 320-1 and/or the second fillers 320-2, any material may be used.

In an embodiment, the binder 310 may not only fix the first fillers 320-1 and the second fillers 320-2 but may also absorb inner impacts applied to the display apparatus 1. That is, due to a modulus characteristic of the binder 310 itself, the binder 310 may be configured to protect the display panel 10 from impacts transferred from below the protective member PB. The impact resistance of the resin coated layer 300 may be improved by not only the elasticity of the binder 310 itself but also by the content of the plurality of fillers and/or the content of the foaming agent 340 described below. In an embodiment, with a standard in which a steel ball of about 2.0 g is dropped from a height of about 10 cm, the amount of impact received by a pressure sensitive paper disposed under the resin coated layer 300 may be about 10 MPa to about 40 MPa.

In addition, in an embodiment, the resin coated layer 300 may further include a solvent (not shown) configured to dissolve the binder 310. The solvent may be volatilized during the thermal curing of the resin coated layer 300, but also may partially remain in the resin coated layer 300. The solvent included in the resin coated layer 300 may have a boiling point of about 100° C. to about 200° C. This is because, in the case where the boiling point of the solvent is about 100° C. or less, the solvent may be volatilized during a process of forming the resin coated layer 300 performed before the thermal curing process. In addition, because the solvent should be compatible with the binder including at least one of an acrylic resin, a urethane resin, a silicone resin, and/or a rubber resin, the solvent may include at least one of an alcohol-based solvent, an ester-based solvent, a ketone-based solvent, and/or a glycol-based solvent. Specifically, the solvent may include an alcohol-based solvent such as isobutanol, butanol, and/or 2-(2-ethoxyethoxy) ethanol. The solvent may include an ester-based solvent such as butyl acetate and/or isobutyl acetate. The solvent may include a ketone-based solvent such as methyl isobutyl ketone. The solvent may include a glycol-based solvent such as propylene glycol methyl ether (PGME) and/or ethylene glycol monopropyl ether (EGPE).

Next, in an embodiment, the light-blocking material 330 may be configured to block light incident from below the display panel 10 and/or reduce reflectivity of light transmitted from above the display panel 10. Specifically, the light-blocking material 330 may include at least one of carbon black, black pigment, and black dye. In the case where the first fillers 320-1 and/or the second fillers 320-2 include a carbon-based material, the first fillers 320-1 and/or the second fillers 320-2 may partially block light. However, the light-blocking material 330 may be further included to further reduce a transmittance of light incident from the lower portion. In an embodiment, the light-blocking material 330 may be included in the content of about 1 wt % to about 5 wt % with respect to a total weight of the resin coated layer 300. In this case, the transmittance of the protective member PB may be about 0.1% or less, and an optical density (OD) of the protective member PB calculated by Equation 1 below may be about 3.0 or more.

$$A = {log}_{10} ( \frac{{P}_{0}}{P} ) \qquad < Equation 1 >$$

In an embodiment, in Equation 1, A denotes an optical density, P₀ denotes light intensity before light passes through the protective member PB, and P denotes intensity of light after light passes through the protective member PB. That is, in the case where the light-blocking material 330 is added by about 1 wt % to about 5 wt %, a light-absorbing ability of the resin coated layer 300 improves and light leakage may be effectively blocked.

Next, in an embodiment, foaming agents 340 and 340′ may be materials whose volume increases when the temperature increases and/or when irradiated with ultraviolet rays. FIG. 7A is a view of a state before the volume of the foaming agent 340 increases, and FIG. 7B is a view of a state after the volume of the foaming agent 340′ increases. The foaming agents 340 and 340′ may have a structure including a core portion and an outer skin surrounding the core portion. When heat and/or ultraviolet rays are provided, a foaming material included in the core portion may be evaporated, and thus, the volume of the foaming agents 340 and 340′ may increase. The volume of the core portion of the foaming agent 340′ after foaming may increase, and the thickness of the outer skin may be thinner than that of the foaming agent 340 before foaming.

In an embodiment, the foaming agents 340 and 340′ may be thermo-expandable microcapsules. That is, when the foaming agent 340 is heated, the foaming material evaporates, and simultaneously, the outer skin is softened and the volume may expand. The foaming agents 340 and 340′ may be low-temperature foaming agents, and a foaming start temperature of the foaming agents 340 and 340′ may be a level of about 70° C. In the case where the low-temperature foaming agent is included in the resin coated layer 300, the foaming process may be performed with the resin coated layer 300 directly coated under the substrate 100 as shown in FIG. 6. That is, because the foaming agent 340 may be foamed at a low temperature, the foaming process may be performed without damaging the organic light-emitting element included in the display panel 10.

In an embodiment, a thermal curing process and a drying process of the resin coated layer 300 may be simultaneously performed using a heat-treating process for foaming the foaming agent 340. However, the embodiment is not limited thereto and the foaming process of the foaming agent 340 and/or the thermal curing process of the resin coated layer 300 may be performed separately.

In an embodiment, the foaming agents 340 and 340′ may be included in the content of about 1 wt % to about 10 wt % with respect to the total weight of the resin coated layer 300. The resin coated layer 300 may be allowed to have preset elastic force and/or a preset impact resistance by adjusting the content of the foaming agents 340 and 340′. When the content of the foaming agent 340 is small, impacts applied to the resin coated layer 300 may not be easily absorbed and elastic force may be reduced. When the content of the foaming agent 340 is large, the durability of the resin coated layer 300 may be reduced. Accordingly, the content adjustment in a proper range may be required.

In an embodiment, the foaming agents 340 and 340′ may be dispersed in the resin coated layer 300, and the sizes of the plurality of foaming agents 340 and 340′ may be identical to each other. In an embodiment, the particle diameter of the foaming agent 340′ after foaming may be about 10 μm to about 100 μm. However, the embodiment is not limited thereto and the sizes of the foaming agents 340 and 340′ may be different from each other. In addition, although it is shown in FIGS. 7A and 7B that the foaming agents 340 and 340′ have a spherical shape, the embodiment is not limited thereto and the foaming agents 340 and/or 340′ may have an elliptical shape.

In addition, in an embodiment, as the volume of the foaming agents 340 and 340′ increases, a region in which the first fillers 320-1 of the resin coated layer 300 may be dispersed may be reduced. That is, when the volume of the foaming agents 340 and 340′ increases, the first fillers 320-1 may be arranged to be more adjacent to each other and some of the first fillers 320-1 may contact each other to form a heat dissipation path. As a result, when the resin coated layer 300 includes the foaming agents 340 and 340′, because a heat dissipation path of the first fillers 320-1 having a heat dissipation characteristic may be more easily formed, the protective member PB may be configured to effectively dissipate heat occurring from the display panel 10. Accordingly, a thermal conductivity of the resin coated layer 300 including the foaming agents 340 and 340′ and the first fillers 320-1 may be about 10 W/mK to about 50 W/mK.

In an embodiment, the resin coated layer 300 may be formed to be in direct contact with the lower surface of the substrate 100. Specifically, a mixture including the first fillers 320-1, the binder 310, the second fillers 320-2, the light-blocking material 330, the foaming agent 340, and/or the solvent (not shown) may be prepared, and the relevant mixture may be directly coated on the lower surface of the substrate 100. The mixture may be coated using one of a printing method, a coating method, and/or a dispensing method. The mixture coated on the lower surface of the substrate 100 may be heat-cured, the solvent thereof may be removed, and/or the volume of the foaming agent 340′ may be expanded through the heat-treatment process. The heat-treatment process may be performed at a temperature of about 25° C. to about 100° C. or less such that the display panel 10 including the display layer 200 is not damaged. The resin coated layer 300 may be formed on the lower surface of the substrate 100 through this process.

In an embodiment, the resin coated layer 300 directly coated and formed on the lower surface of the substrate 100 may be configured to perform a multi-function of protecting the display panel 10. Specifically, the protective member PB including the resin coated layer 300 may be configured to protect the display panel 10 from impacts transferred from the lower portion, perform a heat dissipation function, and/or block electromagnetic waves and light. In the related art, to perform the protection function, a plurality of functional layers respectively having an impact resistance function, a heat dissipation function, an electromagnetic wave blocking function, and/or a light-blocking function are manufactured, and then one composite sheet may be formed through a laminating process. The protective member may be formed by attaching the composite sheet to the display panel through a laminating process. Accordingly, a protective member according to the related art has a high unit price due to a manufacturing process and a laminating process of a plurality of functional layers, and a risk of defect occurrence is higher. In contrast, as shown in FIG. 6, in the case where the protective member PB is formed by directly coating the resin coated layer 300 on the lower surface of the substrate 100, while a multi-function of protecting the display panel 10 is performed, manufacturing costs may be reduced through simplification of the structure and/or the material, and the process may be simplified, and thus, a risk of defect occurrence may be remarkably reduced.

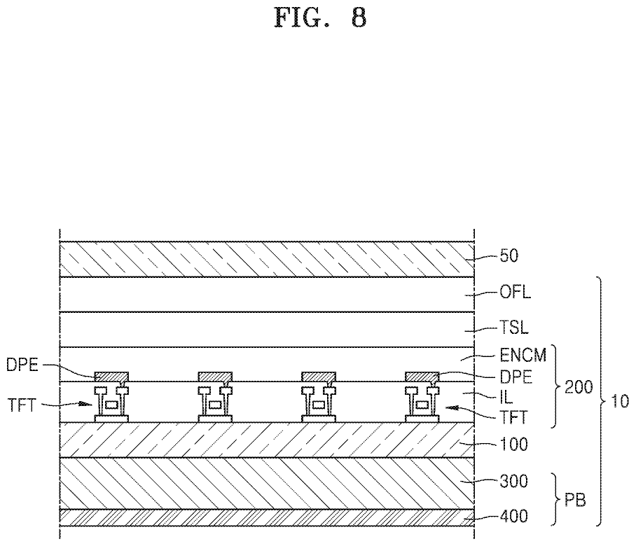

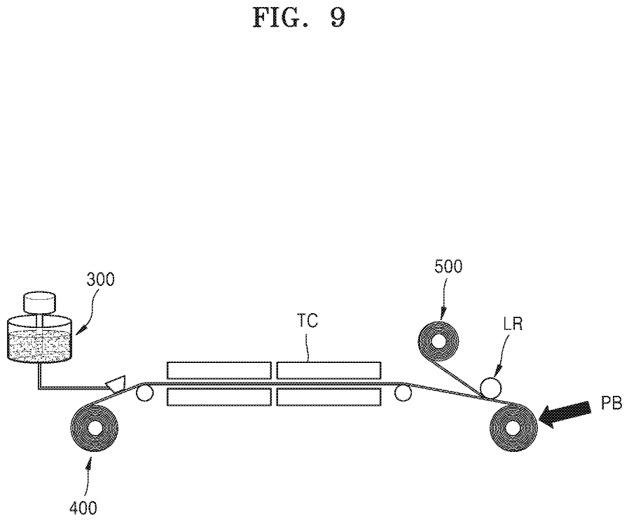

FIG. 8 is a schematic cross-sectional view of a portion of the display panel 10 according to another embodiment, and FIG. 9 is a schematic view of a process of manufacturing the display panel 10 according to another embodiment. In an embodiment, referring to FIGS. 8 and 9, the other characteristics except for the characteristic of the protective member PB are the same as those described with reference to FIGS. 6 to 7B. Same reference numerals among elements of FIGS. 8 and 9 are replaced with those previously described with reference to FIGS. 6 to 7B, and differences are mainly described below.

In an embodiment, the protective member PB may be disposed under the substrate 100. The protective member PB may include the resin coated layer 300 and a metal base layer 400. The entire thickness of the protective member PB may be about 150 μm to about 300 μm, and the thickness of the metal base layer 400 included in the protective member PB may be about 5 μm to about 50 μm.

As described above with reference to FIGS. 6 to 7B, in an embodiment, the resin coated layer 300 may include the binder 310 (see FIG. 7A), the first filler 320-1 (see FIG. 7A), the second filler 320-2 (see FIG. 7A), the light-blocking material 330 (see FIG. 7A), and the foaming agent 340 (see FIG. 7A). Accordingly, the resin coated layer 300 may be configured to perform a multi-function of protecting the display panel 10. Specifically, the protective member PB including the resin coated layer 300 may be configured to protect the display panel 10 from impacts transferred from the lower portion, perform a heat dissipation function, and block electromagnetic waves and light.

In an embodiment, the metal base layer 400 may be disposed on the opposite side of the substrate 100 with the resin coated layer 300 therebetween. That is, the substrate 100 may be disposed on one side of the resin coated layer 300, and the metal base layer 400 may be disposed on another side opposite to one side of the resin coated layer 300. The metal base layer 400 may include a material having excellent thermal conductivity and/or electrical conductivity, and may have heat dissipation and/or electromagnetic waves shielding characteristics. In an embodiment, the metal base layer 400 may be a copper foil including copper (Cu). One surface of the metal base layer 400 may be nodule-processed to secure adhesiveness with the resin coated layer 300.

Referring to FIG. 9, in an embodiment, the resin coated layer 300 may not be directly coated on the lower surface of the substrate 100 but may be directly coated on the upper surface of the metal base layer 400. Specifically, a mixture for the resin coated layer 300 including the first filler 320-1 (see FIG. 7A), the binder 310 (see FIG. 7A), the second filler 320-2 (see FIG. 7A), the light-blocking material 330 (see FIG. 7A), the foaming agent 340 (see FIG. 7A), and the solvent (not shown) may be prepared, and the relevant mixture may be directly coated on one side of the metal base layer 400. The mixture may be coated using one or more of a printing method, a coating method, and a dispensing method.

In an embodiment, the metal base layer 400 on which the mixture for the resin coated layer 300 is coated may be heat-treated using a dry-curing apparatus TC. Through the heat-treating process, the solvent included in the mixture may be removed and heat-cured, and the foaming agent 340 (see FIG. 7A) may be expanded. In the case of the heat-treating process, because the resin coated layer 300 is not directly coated on the lower surface of the display panel 10, there may be no limitation in the temperature of the heat-treating process. As an example, the dry-curing apparatus TC may include a plurality of drying chambers, and the drying chambers may respectively perform curing and drying processes at temperatures of about 60° C., about 80° C., about 100° C., about 120° C., about 140° C., and/or about 160° C.

In an embodiment, an embossed pattern may be formed on one side of the resin coated layer 300 that passes through the dry-curing apparatus TC using a release film 500. Specifically, the release film 500 may include embossed pattern, and include a plurality of intaglio portions and a plurality of embossed portions in the thickness direction. The release film 500 may be attached to one surface of the resin coated layer 300, and an embossed pattern complementary to the embossed pattern of the release film 500 may also be formed on one surface of the resin coated layer 300.

In an embodiment, the release film 500 may be removed and one surface of the resin coated layer 300 on which the embossed pattern is formed may be attached to the lower surface of the substrate 100. The protective member PB including the resin coated layer 300 and/or the metal base layer 400 may be attached to the lower surface of the substrate 100 through a laminating process that uses a lamination roll LR. In the case where the resin coated layer 300 includes the embossed pattern, when the protective member PB is attached to the lower surface of the display panel 10, the embossed pattern may serve as an air passage and may reduce air bubbles. That is, when the protective member PB is completely attached to the lower surface of the display panel 10, the embossed shape on the upper surface of the resin coated layer 300 collapses and the resin coated layer 300 may become flat.

Consequently, in the protective member PB according to another embodiment, the resin coated layer 300 not only performs a multi-function of protecting the display panel 10 but also the metal base layer 400 may be disposed in the protective member PB to improve a heat dissipation function and/or an electromagnetic wave shielding function even more. In addition, because the resin coated layer 300 is directly coated on the metal base layer 400 instead of the substrate 100, the heat-treating temperature of the heat-curing and/or drying processes of the resin coated layer 300 may be flexibly set. Furthermore, the protective member PB shown in FIG. 8 may be a composite sheet having a simplified structure compared to a protective member. Accordingly, manufacturing costs may be reduced and a defect occurrence rate may be reduced.

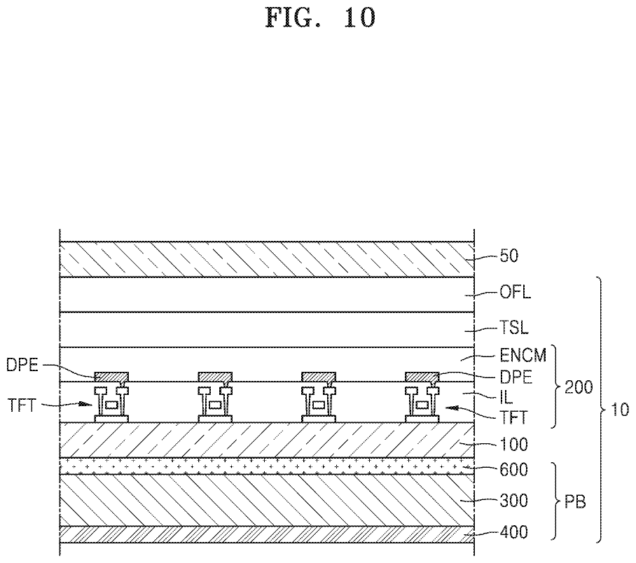

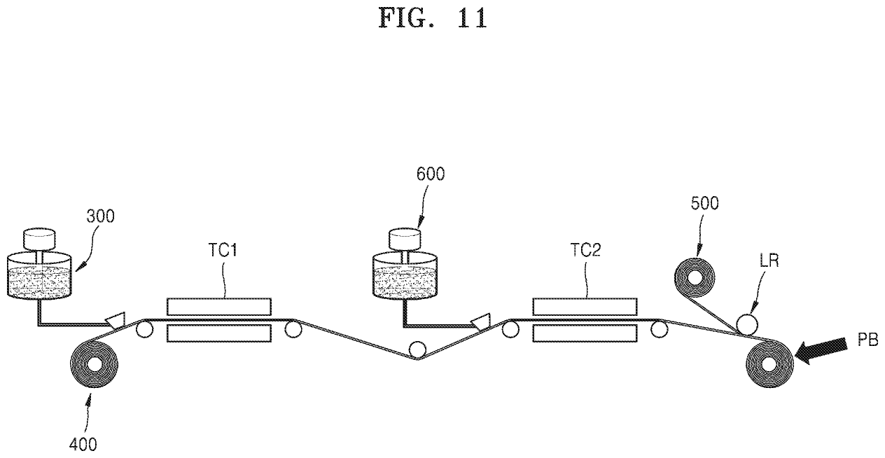

FIG. 10 is a schematic cross-sectional view of a portion of the display panel 10 according to another embodiment, and FIG. 11 is a schematic view of a process of manufacturing the display panel 10 according to another embodiment. Referring to FIGS. 10 and 11, in an embodiment, the other characteristics except for the characteristic of the protective member PB may be the same as those described with reference to FIGS. 8 and 9. Same reference numerals among elements of FIGS. 10 and 11 are replaced with those previously described with reference to FIGS. 8 and 9, and differences are mainly described below.

In an embodiment, the protective member PB may be disposed under the substrate 100. The protective member PB may include the resin coated layer 300, the metal base layer 400, and/or an adhesive layer 600. The entire thickness of the protective member PB may be about 150 μm to about 300 μm, and the thickness of the metal base layer 400 included in the protective member PB may be about 5 μm to about 50 μm. In addition, the thickness of the adhesive layer 600 included in the protective member PB may be about 20 μm to about 40 μm.

In an embodiment, the protective member PB may include a structure in which the metal base layer 400, the resin coated layer 300, and/or the adhesive layer 600 are sequentially stacked. That is, the adhesive layer 600 may be disposed on one surface of the resin coated layer 300, and the metal base layer 400 may be disposed on another surface of the resin coated layer 300. In addition, the resin coated layer 300 may be disposed on one surface of the adhesive layer 600, and the substrate 100 may be disposed on another surface of the adhesive layer 600. Accordingly, the protective member PB may be attached to the display panel 10.

As described above, in an embodiment, the metal base layer 400 may include copper (Cu) having excellent thermal conductivity and electrical conductivity. That is, the metal base layer 400 may be copper foil. Accordingly, the metal base layer 400 may be configured to improve the heat dissipation characteristic and the electromagnetic waves shielding characteristic of the protective member PB even more.

As described above, in an embodiment, the resin coated layer 300 may include the binder 310 (see FIG. 7A), the first filler 320-1 (see FIG. 7A), the second filler 320-2 (see FIG. 7A), the light-blocking material 330 (see FIG. 7A), and the foaming agent 340 (see FIG. 7A). Accordingly, the resin coated layer 300 may be configured to perform a multi-function of protecting the display panel 10. Specifically, the protective member PB including the resin coated layer 300 may be configured to protect the display panel 10 from impacts transferred from the lower portion, perform a heat dissipation function, and block electromagnetic waves and light.

Particularly, in an embodiment, the resin coated layer 300 of FIG. 9 mayinclude more first fillers 320-1 having a heat dissipation characteristic. In an embodiment, the first fillers 320-1 may be included in the content of about 50 wt % to about 90 wt % with respect to a total weight of the resin coated layer 300. The resin coated layer 300 including the first fillers 320-1 of the above content may further improve a heat dissipation characteristic of the protective member PB.

In an embodiment, however, when the content of the first fillers 320-1 are in the resin coated layer 300, an adhesive force of the resin coated layer 300 may be reduced. Accordingly, the resin coated layer 300 containing fillers of a preset level or more may be difficult to directly attach to the lower surface of the display panel 10. To solve this, the protective member PB may further include the adhesive layer 600 disposed between the resin coated layer 300 and the substrate 100. Because the adhesive layer 600 should attach the protective member PB to the display panel 10, the adhesive layer 600 may include material having high adhesive force. In an embodiment, the adhesive layer 600 may include a pressure sensitive adhesive (PSA).

Referring to FIG. 11, like FIG. 9, in an embodiment, the resin coated layer 300 may not be directly coated on the lower surface of the substrate 100 but may be directly coated on the upper surface of the metal base layer 400. Specifically, a mixture for the resin coated layer 300 including the first fillers 320-1, the binder 310, the second fillers 320-2, the light-blocking material 330, the foaming agent 340, and/or the solvent (not shown) may be prepared, and the relevant mixture may be directly coated on one surface of the metal base layer 400. In this case, the mixture for the resin coated layer of FIG. 11 may include more first fillers 320-1 than the mixture for the resin coated layer of FIG. 9. The mixture may be coated using one or more of a printing method, a coating method, and a dispensing method.

In an embodiment, the metal base layer 400 on which the mixture for the resin coated layer 300 is coated may be first heat-treated using a first dry-curing apparatus TC1. Through the first heat-treating process, the solvent included in the mixture may be removed and heat-cured, and the foaming agent 340 (see FIG. 7A) may be expanded. In the case of the heat-treating process, because the resin coated layer 300 is not directly coated on the lower surface of the display panel 10, there may be no limitation in the temperature of the heat-treating process.

Next, in an embodiment, the adhesive layer 600 may be additionally coated on one surface of the resin coated layer 300 that passes through the first dry-curing apparatus TC1. The protective member PB on which the metal base layer 400, the resin coated layer 300, and the adhesive layer 600 may be sequentially coated and may be second heat-treated using a second dry-curing apparatus TC2. The adhesive layer 600 may be heat-cured and dried through the second heat-treating process.

In addition, in an embodiment, an embossed pattern may be formed on one side of the adhesive layer 600 that passes through the second dry-curing apparatus TC2 using the release film 500. Specifically, the release film 500 may include embossed pattern, and include a plurality of intaglio portions and a plurality of embossed portions in the thickness direction. The release film 500 may be attached to one surface of the adhesive layer 600, and an embossed pattern complementary to the embossed pattern of the release film 500 may also be formed on one surface of the adhesive layer 600.

In an embodiment, the release film 500 may be removed and one surface of the adhesive layer 600 on which the embossed pattern is formed may be attached to the lower surface of the substrate 100. The protective member PB including the resin coated layer 300, the metal base layer 400, and the adhesive layer 600 may be attached to the lower surface of the substrate 100 through a laminating process that uses a lamination roll LR. In the case where the adhesive layer 600 includes the embossed pattern, when the protective member PB is attached to the lower surface of the display panel 10, the embossed pattern serves as an air passage and reduces air bubbles. That is, when the protective member PB is completely attached to the lower surface of the display panel 10, the embossed shape on the upper surface of the adhesive layer 600 collapses and the adhesive layer 600 may become flat.

Consequently, in the protective member PB according to another embodiment, the resin coated layer 300 not only performs a multi-function of protecting the display panel 10 but also the metal base layer 400 may be disposed in the protective member PB to improve a heat dissipation function and an electromagnetic wave shielding function even more. Particularly, because the protective member PB according to another embodiment include more first fillers 320-1, heat occurring from the display panel 10 may 10 may be more effectively dissipated. In addition, because the resin coated layer 300 is directly coated on the metal base layer 400 instead of the substrate 100, the heat-treating temperature of the heat-curing and drying processes of the resin coated layer 300 may be flexibly set. Furthermore, the protective member PB shown in FIG. 10 may be a composite sheet having a simplified structure compared to a protective member.

Accordingly, manufacturing costs may be reduced and a defect occurrence rate may be reduced.

The display apparatus according to an embodiment may be configured to perform a multi-function including heat dissipation, electromagnetic waves shielding, light blocking, impact absorption, and the like through a composite resin including fillers and a foaming agent. However, this effect is an example, and the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims. The embodiments of the present disclosure disclosed in the present disclosure and illustrated in the drawings are provided as particular examples for more easily explaining the technical contents according to the present disclosure and helping understand the embodiments of the present disclosure, but not intended to limit the scope of the embodiments of the present disclosure. Accordingly, the scope of the various embodiments of the present disclosure should be interpreted to include, in addition to the embodiments disclosed herein, all alterations or modifications derived from the technical ideas of the various embodiments of the present disclosure. Moreover, the embodiments or parts of the embodiments may be combined in whole or in part without departing from the scope of the invention.

What is claimed is:

1. A display apparatus comprising:
a substrate;
a display layer disposed on a first surface of the substrate; and
a protective member disposed on a second surface of the substrate located opposite to the first surface, wherein the protective member includes a resin coated layer,
wherein the resin coated layer includes a plurality of first fillers having a heat-dissipating characteristic, a binder and a foaming agent.

2. The display apparatus of claim 1, wherein the plurality of first fillers include plate-shaped fillers or linear fillers.

3. The display apparatus of claim 2, wherein a portion of the plurality of first fillers are in contact with each other to form a heat-dissipating path.

4. The display apparatus of claim 1, wherein the plurality of first fillers include at least one of a carbon-based material and a ceramic-based material.

5. The display apparatus of claim 4, wherein the carbon-based material includes at least one of graphite, carbon nanotube (CNT), and carbon fiber, and the ceramic-based material includes at least one of boron nitride (BN), aluminum nitride (AlN), beryllium oxide (BeO), silicon carbide (SiC), and aluminum oxide (Al₂O₃).

6. The display apparatus of claim 1, wherein the plurality of first fillers are included in content in a range of about 50 wt % to about 80 wt % with respect to a total weight of the resin coated layer.

7. The display apparatus of claim 1, wherein a particle diameter of at least one of the plurality of first fillers is in a range of about 10 μm to about 100 μm.

8. The display apparatus of claim 1, wherein the resin coated layer further includes a plurality of second fillers configured to absorb electromagnetic waves, and
wherein the plurality of second fillers include at least one of a carbon-based material and a metal-based material.

9. The display apparatus of claim 8, wherein, the carbon-based material includes at least one of carbon fiber and carbon nanotube (CNT), and
the metal-based material includes at least one of silver-copper (Ag-Cu), nickel-copper (Ni-Cu), Ag nano wire, and silver-nickel (Ag-Ni) powder.

10. The display apparatus of claim 8, wherein the plurality of second fillers are included in content in a range of about 1 wt % to about 10 wt % with respect to a total weight of the resin coated layer.

11. The display apparatus of claim 8, wherein the plurality of first fillers and the plurality of second fillers are included in content in a range of about 51 wt % to about 90 wt % with respect to a total weight of the resin coated layer.

12. The display apparatus of claim 1, wherein the binder includes at least one of an acrylic resin, a urethane resin, a silicone resin, and a rubber resin.

13. The display apparatus of claim 1, wherein the foaming agent is a thermo-expandable microcapsule.

14. The display apparatus of claim 13, wherein a particle diameter of the foaming agent is in a range of about 10 μm to about 100 μm.

15. The display apparatus of claim 1, wherein the resin coated layer further includes a first light-blocking material, wherein
the first light-blocking material includes at least one of carbon black, black pigment, and black dye.

16. The display apparatus of claim 15, wherein the first light-blocking material is included in content in a range of about 1 wt % to about 5 wt % with respect to a total weight of the resin coated layer.

17. The display apparatus of claim 1, wherein a thickness of the resin coated layer after curing is in a range of about 100 μm to about 300 μm.

18. The display apparatus of claim 1, wherein an optical density of the resin coated layer is about 3.0 or more.

19. The display apparatus of claim 1, wherein a thermal conductivity of the resin coated layer in a planar direction is about 10 W/mK to about 50 W/mK.

20. The display apparatus of claim 1, wherein the resin coated layer has an impact resistance in a range of about 10 MPa to about 40 MPa or less when an about 2.0 g-steel ball is dropped from a height of about 10 cm.

21. The display apparatus of claim 1, wherein an electromagnetic wave-shielding rate of the resin coated layer is in a range of about 40 dB to about 90 dB.

22. The display apparatus of claim 1, wherein the protective member further includes a metal base layer,
wherein the metal base layer is disposed on an opposite side of the substrate with the resin coated layer located therebetween.

23. The display apparatus of claim 22, wherein the metal base layer includes copper (Cu).

24. The display apparatus of claim 22, wherein a thickness of the metal base layer is in a range of about 5 μm to about 50 μm.

25. The display apparatus of claim 22, wherein the protective member further includes an adhesive layer disposed between the substrate and the resin coated layer,
wherein the adhesive layer includes a pressure sensitive adhesive (PSA).

26. A method of manufacturing a display apparatus, the method comprising:
forming a display layer disposed on one surface of a substrate; and
forming a protective member disposed on an other surface located opposite to the one surface of the substrate,
wherein the forming of the protective member includes forming a resin coated layer including a plurality of first fillers having a heat-dissipating characteristic, a binder, and a foaming agent.

27. The method of claim 26, wherein the forming of the resin coated layer comprises preparing a mixture of the plurality of first fillers, the binder, the foaming agent, and a solvent,
wherein a boiling point of the solvent is in a range of about 100° C. to about 200° C.

28. The method of claim 27, wherein the forming of the resin coated layer further comprises:
coating the other surface of the substrate with the mixture; and
curing the mixture to remove the solvent and expanding the foaming agent.

29. The method of claim 28, wherein the coating of the mixture includes at least one of a printing method, a coating method, and a dispensing method.

30. The method of claim 28, wherein the curing of the mixture comprises heat-treating the mixture at a temperature range of about 25° C. to about 100° C. or less.

31. The method of claim 30, wherein a particle diameter of the foaming agent expanded after the heat-treating is in a range of about 10 μm to about 100 μm.

32. The method of claim 27, wherein the forming of the protective member comprises:
forming a metal base layer including copper (Cu);
coating the metal base layer with the resin coated layer; and
curing the mixture to remove the solvent and expanding the foaming agent.

33. The method of claim 32, wherein the forming of the protective member further comprises forming an embossed shape on an other surface located opposite to one surface of the resin coated layer facing the metal base layer.

34. The method of claim 32, wherein the forming of the protective member further comprises forming an adhesive layer on an other surface located opposite to one surface of the resin coated layer facing the metal base layer.

35. The method of claim 32, further comprising laminating the protective member on the other surface of the substrate.
